(19) United States
(12) Patent Application Publication
(10) Pub. No.: US 2026/0198322 A1
(43) Pub. Date: Jul. 9, 2026

(54) ELECTRONIC DEVICE AND METHOD OF MANUFACTURING THE SAME

(71) Applicant: Advanced Semiconductor Engineering, Inc., Kaohsiung (TW)

(72) Inventors: Chien-Fan CHEN, Kaohsiung (TW); Chia-Pin CHEN, Kaohsiung (TW); Chia-Chun YEN, Kaohsiung (TW); Chia Sheng TIEN, Kaohsiung (TW)

(73) Assignee: Advanced Semiconductor Engineering, Inc., Kaohsiung (TW)

(21) Appl. No.: 19/074,301

(22) Filed: Mar. 7, 2025

Related U.S. Application Data
(60) Provisional application No. 63/741,798, filed on Jan. 3, 2025.

(51) Int. Cl. H01L 23/00; H01L 23/31; H01L 23/498; H01L 23/538

(52) U.S. Cl. CPC H10W 42/121; H10W 70/611; H10W 70/65; H10W 74/111; H10W 90/701

(57) ABSTRACT

The present disclosure provides an electronic device and a method of manufacturing an electronic device. The electronic device includes a passive component having a lower surface and an upper surface opposite to the lower surface. The electronic device also includes a first warpage-control layer disposed under the lower surface. The electronic device further includes a second warpage-control layer disposed over the upper surface.

### CROSS-REFERENCE TO RELATED APPLICATION

This application claims the benefit and priority to U.S. Provisional Application 63/741,798, filed Jan. 3, 2025, the contents of which are incorporated herein by reference in their entirety.

### BACKGROUND

### 1. Technical Field

The present disclosure relates to an electronic device and a method of manufacturing an electronic device.

### 2. Description of the Related Art

As electronic devices continue to shrink in size, passive components, such as deep trench capacitors (DTC), are often larger to meet electrical requirements. This discrepancy can lead to warpage caused by mismatched coefficients of thermal expansion (CTE), ultimately reducing the manufacturing yield of electronic devices. Therefore, a new electronic device is required.

### SUMMARY

In some arrangements, an electronic device includes a passive component having a lower surface and an upper surface opposite to the lower surface. The electronic device also includes a first warpage-control layer disposed under the lower surface. The electronic device further includes a second warpage-control layer disposed over the upper surface.

In some arrangements, an electronic device includes a redistribution structure. The electronic device also includes a first electronic component over the redistribution structure. The electronic device further includes a passive component under the redistribution structure and electrically connected to the first electronic component. In addition, the electronic device includes a first warpage-control layer between the redistribution structure and the passive component.

In some arrangements, a method of manufacturing an electronic device includes providing a passive component having a first surface and a second surface opposite to the first surface. The method also includes forming a first warpage-control layer under the first surface. The method also further includes forming a second warpage-control layer over the second surface to define an interposer. In addition, the method includes integrating the interposer with an electronic component.

### BRI EF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device, in accordance with some arrangements of the present disclosure.

FIG. 2 illustrates an enlarged view of an interposer of the electronic device as shown in FIG. 1, in accordance with some arrangements of the present disclosure.

FIG. 3A, FIG. 3B, FIG. 3C, FIG. 3D, FIG. 3E, FIG. 3F, FIG. 3G, FIG. 3H, FIG. 3I, FIG. 3J, and FIG. 3K illustrate various stages of an example of a method for manufacturing an interposer according to some embodiments of the present disclosure.

FIG. 4A, FIG. 4B, FIG. 4C, FIG. 4D, FIG. 4E, FIG. 4F, FIG. 4G, FIG. 4H, FIG. 4I, and FIG. 4J illustrate various stages of an example of a method for manufacturing an electronic device according to some embodiments of the present disclosure.

FIG. 5A, FIG. 5B, FIG. 5C, and FIG. 5D illustrate various stages of an example of a method for manufacturing an electronic device according to some embodiments of the present disclosure.

FIG. 6 illustrates a cross-sectional view of an electronic device, in accordance with some arrangements of the present disclosure.

FIG. 7 illustrates a cross-sectional view of an electronic device, in accordance with some arrangements of the present disclosure.

FIG. 8 illustrates a cross-sectional view of an electronic device, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

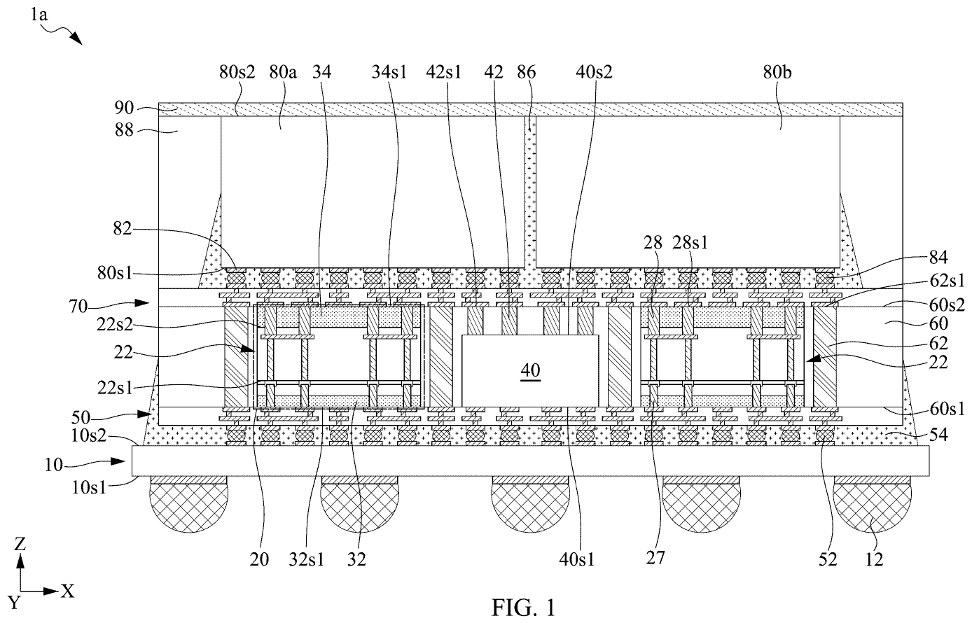

FIG. 1 illustrates an electronic device 1a, in accordance with some arrangements of the present disclosure. In some arrangements, the electronic device 1a may include a circuit structure 10, an interposer 20, a bridge component 40, a redistribution structure 50, an encapsulant 60, a redistribution structure 70, an electronic component 80a, an electronic component 80b, and a conductive layer 90.

The circuit structure 10 (or carrier) may be formed as a printed circuit board (PCB), flexible printed circuit board (FPCB), or other suitable circuit structures. The circuit structure 10 may include multiple metal layers separated from one another by layers of dielectric material and interconnected by electrically conductive vias. In some arrangements, the circuit structure 10 may be formed of an epoxy resin, a fiberglass-reinforced epoxy resin, an epoxy resin with inorganic fillers, a ceramic material, or a polymer material such as polyimide. The circuit structure 10 may have a surface 10s1 (or lower surface) and a surface 10s2 (or upper surface) opposite to the surface 10s1.

In some arrangements, the electronic device 1a may include electrical connections 12. The electrical connections 12 may be disposed on or under the surface 10s1 of the circuit structure 10. The electrical connections 12 may be configured to electrically connect the electronic device 1a and an external device (not shown). The electrical connections 12 may include a reflowable material. The electrical connections 12 may be or include electrical contacts, such as solder balls (e.g., controlled collapse chip connection (C4) bump, a ball grid array (BGA), a land grid array (LGA)), conductive bumps, or the like. The electrical connections 12 may include alloys of gold and tin solder or alloys of silver and tin solder, or other suitable materials.

In some arrangements, the interposer 20 (or passive component interposer) may be disposed on or over the surface 10s2 of the circuit structure 10. In some arrangements, the interposer 20 may be disposed on or over the redistribution structure 50. In some arrangements, the interposer 20 may be electrically connected to the circuit structure 10 through the redistribution structure 50. In some arrangements, the interposer 20 may be electrically connected to the electronic component 80a and/or 80b. In some arrangements, the interposer 20 may be configured to regulate the signal (e.g., power signal or data signal) transmitted to or from the electronic component 80a and/or 80b.

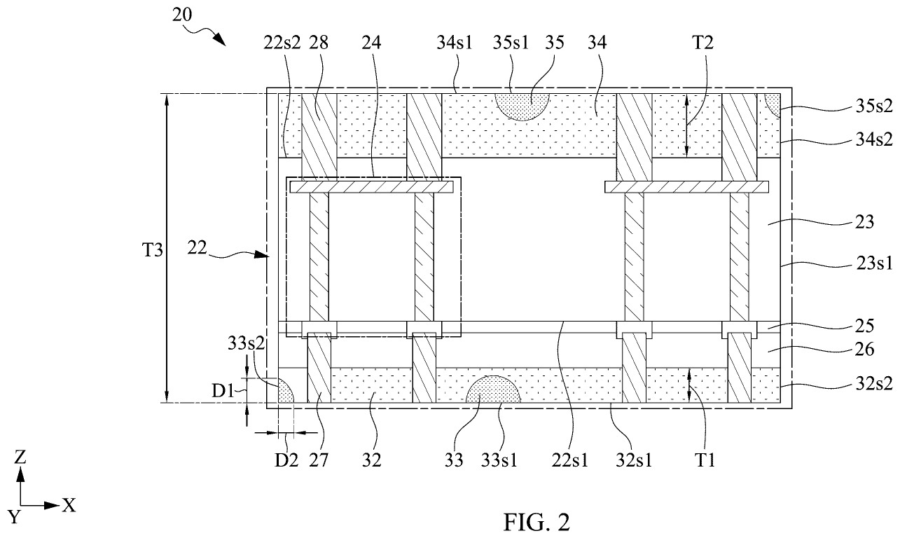

Please refer to FIG. 2, the interposer 20 may include a passive component 22 (or voltage regulator). In some arrangements, the passive component 22 may include a capacitor, such as a deep trench capacitor (DTC), a multi-layer ceramic capacitor (MLCC) or other capacitors. The passive component 22 may have a surface 22s1 (or a lower surface) and a surface 22s2 (or an upper surface) opposite to the surface 22s1. In some arrangements, each of the surface 22s1 and surface 22s2 may function as an active surface. In this disclosure, the active surface may refer to a surface through which a signal (e.g., power signal or data signal) passes. For example, the passive component 22 may include terminals (e.g., input/out (I/O) terminals) abutting the surface 22s1 and surface 22s2 for transmitting signals.

In some arrangements, the passive component 22 may include a substrate 23 and a passive circuit 24. The substrate 23 may include a semiconductor substrate, such as silicon, germanium, and other group III-V and group IV materials. In some arrangements, the lower surface of the substrate 23 may function as the surface 22s1, and the upper surface of the substrate 23 may function as the surface 22s2. The passive circuit 24 may include a capacitor structure. For example, the passive circuit 24 may include a lower electrode, an upper electrode, and a capacitor dielectric therebetween. The passive circuit 24 may penetrate the substrate 23.

The passive component 22 may include a dielectric layer 25 and a protection layer 26. The dielectric layer 25 may be disposed on or under the surface 22s1 of the passive component 22. The dielectric layer 25 may include oxide, nitride, oxynitride, or other suitable dielectric materials. The protection layer 26 may be disposed on or under the dielectric layer 25. In some arrangements, the protection layer 26 may include polyimide, polybenzoxazole, benzocyclobuten, or other suitable materials. In some arrangements, the lower surface of the protection layer 26 may function as the surface 22s1 of the passive component 22.

The passive component 22 may include conductive structures 27 (or conductive posts or terminals). The conductive structures 27 may be disposed on or abut the surface 22s1 of the passive component 22. The conductive structures 27 may be electrically connected to, for example, the lower electrode of the passive component 22. The conductive structures 27 may penetrate the dielectric layer 25. The conductive structures 27 may penetrate the protection layer 26. The conductive structures 27 may include copper, aluminum, chromium, tin, gold, silver, nickel, titanium, or other suitable materials.

The passive component 22 may include conductive structures 28 (or conductive posts or terminals). The conductive structures 28 may be disposed on or abut the surface 22s2 of the passive component 22. The conductive structures 28 may be electrically connected to, for example, the upper electrode of the passive component 22. The conductive structures 28 may include copper, aluminum, chromium, tin, gold, silver, nickel, titanium, or other suitable materials. It should be noted that the passive component 22 may include other traces and/or via for electrical connections.

In some arrangements, the interposer 20 may include a warpage-control layer 32. In some arrangements, the warpage-control layer 32 may be disposed under or abut the surface 22s1 of the passive component 22. In some arrangements, the warpage-control layer 32 may be disposed on or under the protection layer 26. In some arrangements, the conductive structures 27 may penetrate the warpage-control layer 32. In some arrangements, the warpage-control layer 32 may be spaced apart from the substrate 23 by the dielectric layer 25 and/or protection layer 26. In some arrangements, the warpage-control layer 32 may be configured to control and/or modify the warpage of the interposer 20. In some arrangements, the coefficient of thermal expansion of the warpage-control layer 32 may range between about 3 ppm/° C. and about 30 ppm/° C. In other arrangements, the warpage-control layer 32 may include a dielectric material. In some arrangements, the warpage-control layer 32 may include a novolac-based resin, an epoxy-based resin, a silicone-based resin, or another suitable material. The warpage-control layer 32 may include a molding compound formed by using any of a number of molding techniques, such as compression molding, injection molding, or transfer molding. In some arrangements, the warpage-control layer 32 may have a surface 32s1 (or a lower surface) and a surface 32s2 (or a lateral surface). The warpage-control layer 32 may have a thickness T1 along the Z direction. In some arrangements, the surface 32s1 of the warpage-control layer 32 may be substantially aligned with the lower surface of the conductive structures 27. In some arrangements, the warpage-control layer 32 may have a material the same as that of the substrate 23.

In some arrangements, the interposer 20 may include a warpage-control layer 34. In some arrangements, the warpage-control layer 34 may be disposed over or abut the surface 22s2 of the passive component 22. In some arrangements, the warpage-control layer 34 may be in contact with the substrate 23 of the passive component 22. In some arrangements, the conductive structures 28 may penetrate the warpage-control layer 34. In some arrangements, the warpage-control layer 34 may be configured to control and/or modify the warpage of the interposer 20. In some arrangements, the coefficient of thermal expansion of the warpage-control layer 34 may be less than that of the warpage-control layer 32. In some arrangements, the coefficient of thermal expansion of the warpage-control layer 34 may range between about 2 ppm/° C. and about 20 ppm/° C. In other arrangements, the warpage-control layer 34 may include a dielectric material. In some arrangements, the warpage-control layer 34 may include a novolac-based resin, an epoxy-based resin, a silicone-based resin, or another suitable material. The warpage-control layer 34 may include a molding compound formed by using any of a number of molding techniques, such as compression molding, injection molding, or transfer molding. In some arrangements, the warpage-control layer 34 may have a surface 34s1 (or an upper surface) and a surface 34s2 (or a lateral surface). The warpage-control layer 34 may have a thickness T2 along the Z direction. In some arrangements, the thickness T2 may be greater than the thickness T1. In some arrangements, the surface 34s1 of the warpage-control layer 34 may be substantially aligned with the upper surface of the conductive structures 28. In some arrangements, the surface 32s2 of the warpage-control layer 32 may be substantially aligned with the surface 34s2 of the warpage-control layer 34.

In some arrangements, the warpage-control layer 32 may include fillers 33. In some arrangements, one of the fillers 33 may have a surface 33s1 (or truncated surface) exposed by the surface 32s1 of the warpage-control layer 32. In some arrangements, one of the fillers 33 may have a surface 33s2 (or truncated surface) exposed by the surface 32s2 of the warpage-control layer 32. In some arrangements, the surface 33s1 of the filler 33 may be formed by grinding or polishing the warpage-control layer 32. In some arrangements, the surface 33s2 of the filler 33 may be formed by a singulation technique performed on the warpage-control layer 32. In some arrangements, the surface 33s1 of the filler 33 may be in contact with the redistribution structure 50. In some arrangements, the surface 33s2 of the filler 33 may be in contact with the encapsulant 60. In some arrangements, the portion of the filler 33 exposed by the surface 32s1 may have a width (or length) different from that of the portion of the filler 33 exposed by the surface 32s2. For example, the portion of the filler 33 exposed by the surface 32s2 may have a length D1, and the portion of the filler 33 exposed by the surface 32s1 may have a length D2 different from the length D1.

In some arrangements, the warpage-control layer 34 may include fillers 35. In some arrangements, one of the fillers 35 may have a surface 35s1 (or truncated surface) exposed by the surface 34s1 of the warpage-control layer 34. In some arrangements, one of the fillers 35 may have a surface 35s2 (or truncated surface) exposed by the surface 34s2 of the warpage-control layer 34. In some arrangements, the surface 35s1 of the fillers 35 may be formed by grinding or polishing the warpage-control layer 34. In some arrangements, the surface 35s2 of the fillers 35 may be formed by a singulation technique performed on the warpage-control layer 34. In some arrangements, the surface 35s1 of the filler 35 may be in contact with the redistribution structure 70. In some arrangements, the surface 35s2 of the filler 35 may be in contact with the encapsulant 60.

In some arrangements, the substrate 23 may have a surface 23s1 (or a lateral surface). In some arrangements, the surface 23s1 of the substrate 23 may be substantially aligned with the surface 32s2 of the warpage-control layer 32. In some arrangements, the surface 23s1 of the substrate 23 may be substantially aligned with the surface 34s2 of the warpage-control layer 34.

The interposer 20 may have a thickness T3. In some arrangements, the thickness T3 may range between about 40 um to about 50 um. In some arrangements, the interposer 20 may have a surface area (e.g., the area extending along the XY plane) greater than 15×15 mm², such as 15×15 mm², 17×17 mm², 20×20 mm², or more. In some arrangements, the ratio of the surface area to the thickness of the interposer 20 may be greater than 5000 mm, which may cause a significant warpage.

Please refer back to FIG. 1, the warpage-control layer 32 may be disposed between the circuit structure 10 and the passive component 22. In some arrangements, the warpage-control layer 32 may be disposed between the passive component 22 and the redistribution structure 50. In some arrangements, the warpage-control layer 34 may be disposed between the passive component 22 and the redistribution structure 70. In some arrangements, the warpage-control layer 34 may be disposed between the passive component 22 and the electronic component 80a (or electronic component 80b).

The bridge component 40 may be disposed on or over the surface 10s2 of the circuit structure 10. In some arrangements, the bridge component 40 may be disposed on or over the redistribution structure 50. In some arrangements, the bridge component 40 may laterally overlap the interposer 20 or overlap the interposer 20 along the X direction (or Y direction or XY plane). In some arrangements, the bridge component 40 may laterally overlap the passive component 22 or overlap the passive component 22 along the X direction (or Y direction or XY plane). In some arrangements, the bridge component 40 may laterally overlap the warpage-control layer 32 or overlap the warpage-control layer 32 along the X direction (or Y direction or XY plane). In some arrangements, the bridge component 40 may be free from laterally overlapping the warpage-control layer 34 or free from laterally overlapping the warpage-control layer 34 along the X direction (or Y direction or XY plane). In some arrangements, the bridge component 40 may be electrically connected to the electronic components 80a and 80b. In some arrangements, the bridge component 40 may be configured to communicate the electronic components 80a and 80b. For example, the signal may be transmitted from the electronic component 80a to the electronic component 80b through the bridge component 40. In some embodiments, the bridge component 40 may be a bridge die, such as a high-level data link control (HDLC) chip. In some arrangements, the bridge component 40 may be directly or indirectly electrically connected to the interposer 20. The bridge component 40 may have a surface 40s1 (or a lower surface) and a surface 40s2 (or an upper surface) opposite to the surface 40s1. The surface 40s1 of the bridge component 40 may be substantially aligned with the surface 32s1 of the warpage-control layer 32.

The bridge component 40 may include interconnectors 42 over the upper surface (not denoted) of the bridge component 40. The interconnectors 42 may contact or electrically connect the redistribution structure 70. The interconnectors 42 may be electrically connected to the electronic components 80a and 80b through the redistribution structure 70. A surface 42s1 (or upper surface) of the bridge component 40 may be substantially aligned with a surface 28s1 (or upper surface) of the conductive structure 28. The interconnectors 42 may include, for example, copper, another conductive metal, or an alloy thereof.

The redistribution structure 50 may be disposed between the circuit structure 10 and the interposer 20. The redistribution structure 50 may be disposed between the circuit structure 10 and the bridge component 40. The redistribution structure 50 may include conductive layers embedded within a dielectric structure. The redistribution structure 50 may be configured to, for example, electrically connect the interposer 20 and the circuit structure 10.

The electronic device 1a may include electrical connections 52. The electrical connections 52 may be disposed between the circuit structure 10 and the redistribution structure 50. The electrical connections 52 may be configured to electrically connect the circuit structure 10 and the redistribution structure 50. In some arrangements, the electrical connections 52 may include a reflowable material, such as a solder material, which may include alloys of gold and tin solder or alloys of silver and tin solder, or other suitable materials. The electrical connections 52 may be or include electrical contacts, such as solder balls (e.g., controlled collapse chip connection (C4) bump, a ball grid array (BGA), a land grid array (LGA)), conductive bumps, or the like.

The electronic device 1a may include a protection layer 54. In some arrangements, the protection layer 54 may be disposed on or over the surface 10s2 of the circuit structure 10. In some arrangements, the protection layer 54 may cover a portion of a lateral surface of the encapsulant 60. In some arrangements, the protection layer 54 may encapsulate the redistribution structure 50. In some arrangements, the protection layer 54 may encapsulate the electrical connections 52. In some arrangements, the protection layer 54 may include an underfill material, for example, made of epoxy or other suitable materials.

In some arrangements, the encapsulant 60 may be disposed on or over the upper surface (not denoted) of the redistribution structure 50. In some arrangements, the encapsulant 60 may encapsulate the interposers 20. In some arrangements, the encapsulant 60 may encapsulate the passive components 22. In some arrangements, the encapsulant 60 may encapsulate the warpage-control layers 32. In some arrangements, the encapsulant 60 may encapsulate the warpage-control layers 34. In some arrangements, the encapsulant 60 may encapsulate the bridge component 40. In some arrangements, the encapsulant 60 may include a novolac-based resin, an epoxy-based resin, a silicone-based resin, or another suitable material. The encapsulant 60 may include a molding compound formed by using any of a number of molding techniques, such as compression molding, injection molding, or transfer molding. In some arrangements, the encapsulant 60 may have a surface 60s1 (or a lower surface) and a surface 60s2 (or an upper surface). In some arrangements, the surface 60s1 of the encapsulant 60 may be substantially aligned with the surface 32s1 of the warpage-control layer 32. In some arrangements, the surface 60s2 of the encapsulant 60 may be substantially aligned with the surface 34s1 of the warpage-control layer 34. In some arrangements, the coefficient of thermal expansion of the encapsulant 60 may be less than that of the warpage-control layer 32. In some arrangements, the coefficient of thermal expansion of the encapsulant 60 may range between about 2 ppm/° C. and about 20 ppm/° C. In some arrangements, the material of the encapsulant 60 may be different from that of the warpage-control layers 32. In some arrangements, the material of the encapsulant 60 may be different from that of the warpage-control layers 34. The Young's modulus of the encapsulant 60 may range between 5 GPa and 20 GPa at room temperature. The Young's modulus of the encapsulant 60 may range between 0.5 GPa and 2 GPa at a higher temperature (e.g., 100° C.).

The electronic device 1a may include conductive pillars 62 (or conductive elements or vertically electrical connectors). In some arrangements, the conductive pillars 62 may be disposed at the side of the interposer 20. In some arrangements, the conductive pillar 62 may be disposed at the side (or lateral surface) of the warpage-control layer 32. In some arrangements, the conductive pillar 62 may be disposed at the side (or lateral surface) of the warpage-control layer 34. The conductive pillar 62 may be electrically connected to the redistribution structure 50. The conductive pillar 62 may penetrate the encapsulant 60. The conductive pillar 62 may electrically connect the redistribution structure 50 and redistribution structure 70. The conductive pillar 62 may include copper, aluminum, chromium, tin, gold, silver, nickel, titanium, or other suitable materials.

The redistribution structure 70 may be disposed on or over the encapsulant 60. In some arrangements, the redistribution structure 70 may be electrically connected to the interposer 20. In some arrangements, the redistribution structure 70 may be electrically connected to the bridge component 40. In some arrangements, the redistribution structure 70 may be in contact with the warpage-control layer 34. The redistribution structure 70 may include conductive layers embedded within a dielectric structure (e.g., polyimide or other suitable materials).

The electronic components 80a and 80b may be disposed on the redistribution structure 70. In some arrangements, each of the electronic components 80a and 80b may include a semiconductor die or a chip, such as a logic die (e.g., application processor (AP), application-specific IC (ASIC), system-on-a-chip (SoC), central processing unit (CPU), graphics processing unit (GPU), microcontroller, etc.), a memory die (e.g., dynamic random access memory (DRAM) die, static random access memory (SRAM) die, high band memory die (HBM), etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components. For example, the electronic component 80a may include an ASIC, and the electronic component 80b may include an HBM. Each of the electronic components 80a and 80b may have a surface 80s1 (or a lower surface) and a surface 80s2 (or an upper surface) opposite to the surface 80s1. The surface 80s1 may function as an active surface of the electronic component 80a (or electronic component 80b). The surface 80s2 may function as a backside surface of the electronic component 80a (or electronic component 80b).

Each of the electronic components 80a and 80b may be electrically connected to the redistribution structure 70 through pads 82 and electrical connections 84. The pads 82 may include copper, aluminum, chromium, tin, gold, silver, nickel, titanium, or other suitable materials. The electrical connections 84 may include a reflowable material, such as a solder material, which may include alloys of gold and tin solder or alloys of silver and tin solder, or other suitable materials. The electrical connections 84 may be or include electrical contacts, such as solder balls (e.g., controlled collapse chip connection (C4) bump, a ball grid array (BGA), a land grid array (LGA)), conductive bumps, or the like.

In some arrangements, the electronic device 1a may include a protection layer 86. The protection layer 86 may be disposed on or over the upper surface of the redistribution structure 70. The protection layer 86 may fill the gap between the electronic components 80a and 80b. The protection layer 86 may cover the lateral surface (not denoted) of the electronic components 80a and 80b. The protection layer 86 may encapsulate the electrical connections 84. In some arrangements, the protection layer 86 may include an underfill material, for example, made of epoxy or other suitable materials.

In some arrangements, the electronic device 1a may include an encapsulant 88. The encapsulant 88 may be disposed on or over the upper surface of the redistribution structure 70. The encapsulant 88 may encapsulate the electronic components 80a and 80b. The encapsulant 88 may encapsulate the protection layer 86. In some arrangements, the coefficient of thermal expansion of the encapsulant 88 may be less than that of the warpage-control layer 32. In some arrangements, the coefficient of thermal expansion of the encapsulant 88 may range between about 2 ppm/° C. and about 20 ppm/° C. The Young's modulus of the encapsulant 88 may be greater than 20 GPa at room temperature. The Young's modulus of the encapsulant 88 may be greater than 3 GPa at a higher temperature.

In some arrangements, the conductive layer 90 may be disposed on or over the encapsulant 88. In some arrangements, the conductive layer 90 may cover the electronic components 80a and 80b. The conductive layer 90 may be configured to transmit heat from the electronic device 1a to the surrounding environment. The conductive layer 90 may include copper, aluminum, chromium, tin, gold, silver, nickel, titanium, or other suitable materials. In some arrangements, a heat dissipating structure, such as a heat sink, may be disposed over the conductive layer 90.

In a comparative example, no warpage-control layer is formed under and/or over a passive component. In this condition, the passive component experiences significant warpage, particularly when it has a relatively large surface area (e.g., 15×15 mm²). This warpage can lead to failures in bonding the passive component to other devices. To address this issue, the warpage-control layer 32 and warpage-control layer 34 are formed on opposite sides of the passive component 22 to refrain the warpage, thereby enhancing the bonding of the interposer 20 to the redistribution structure 50.

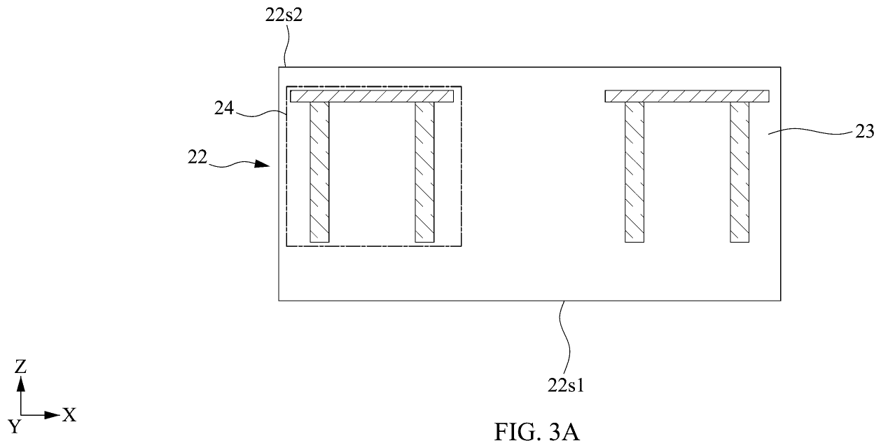

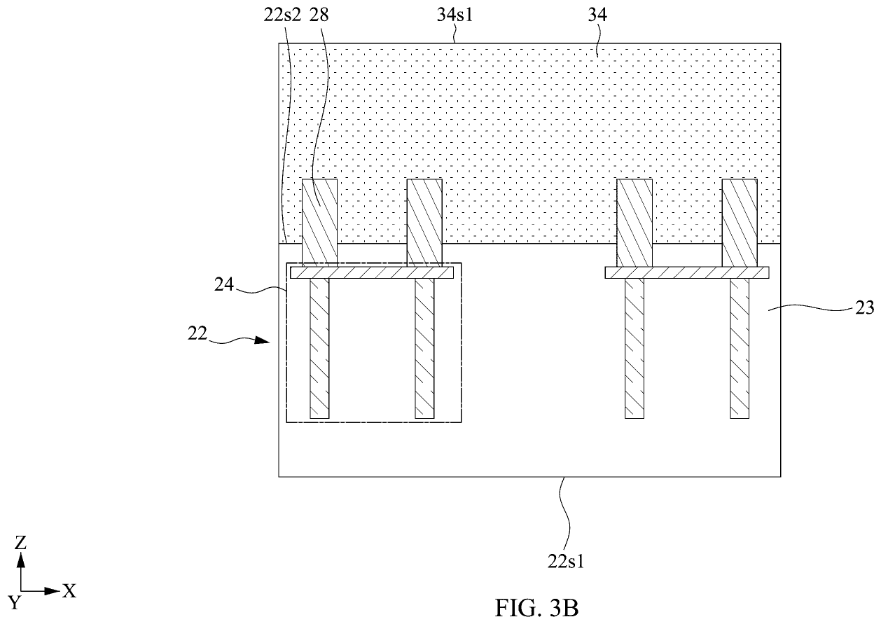

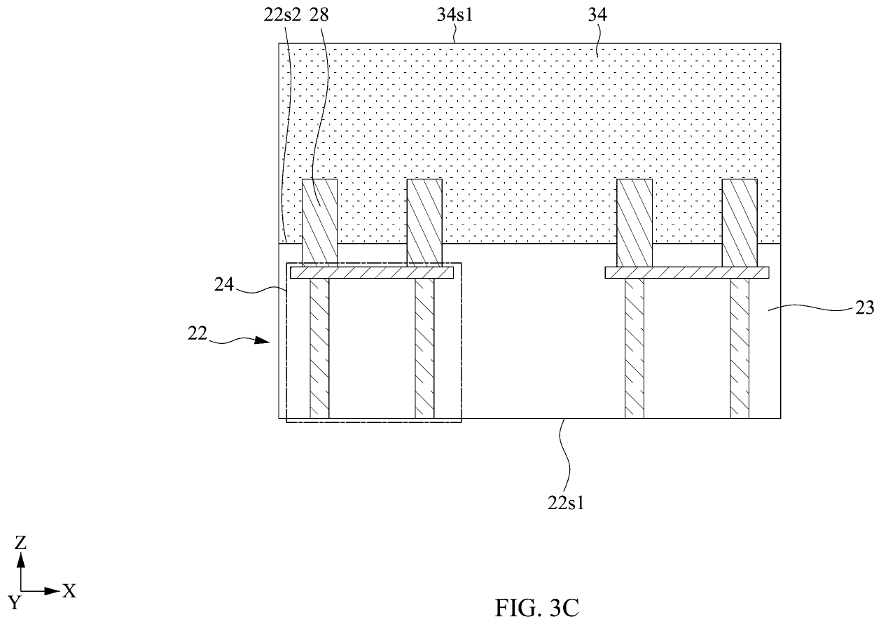

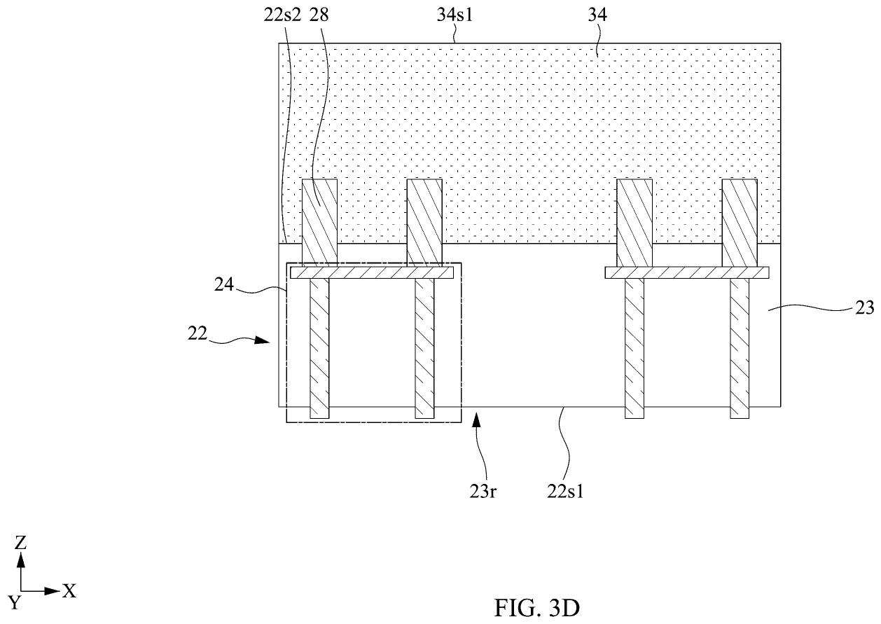

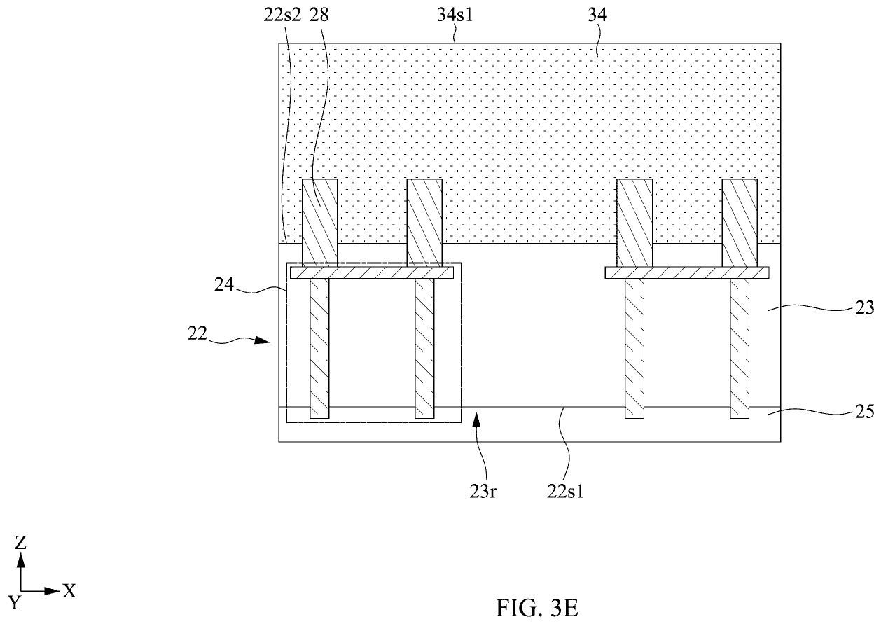

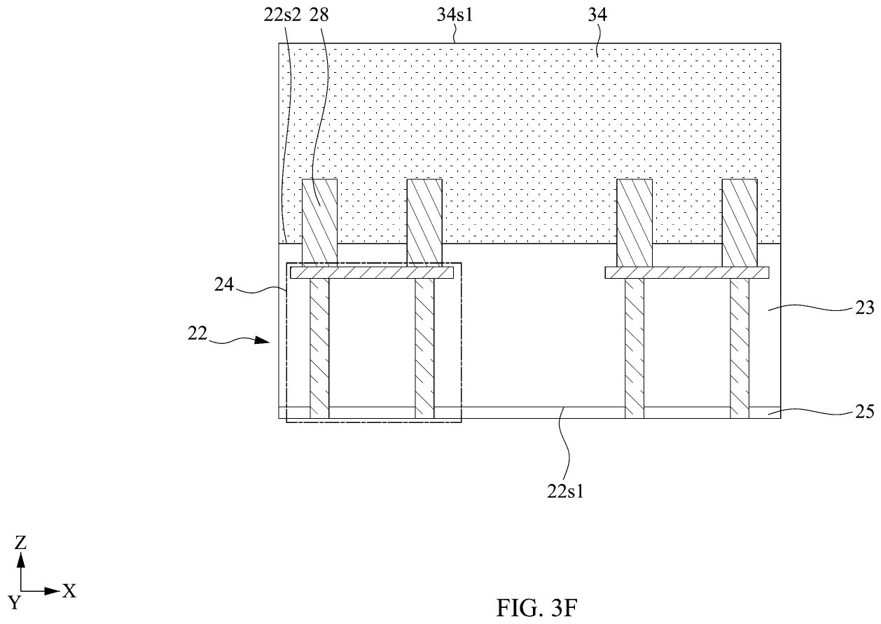

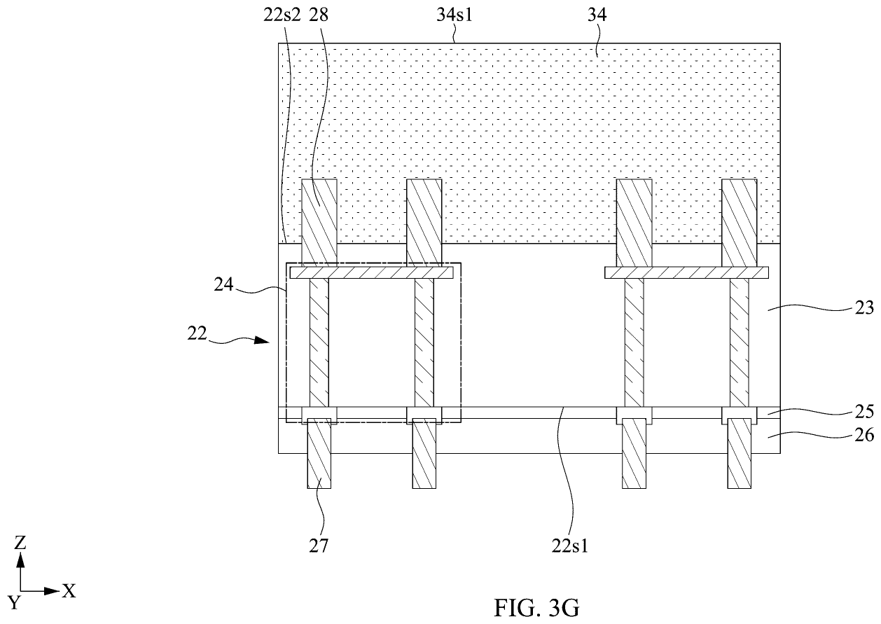

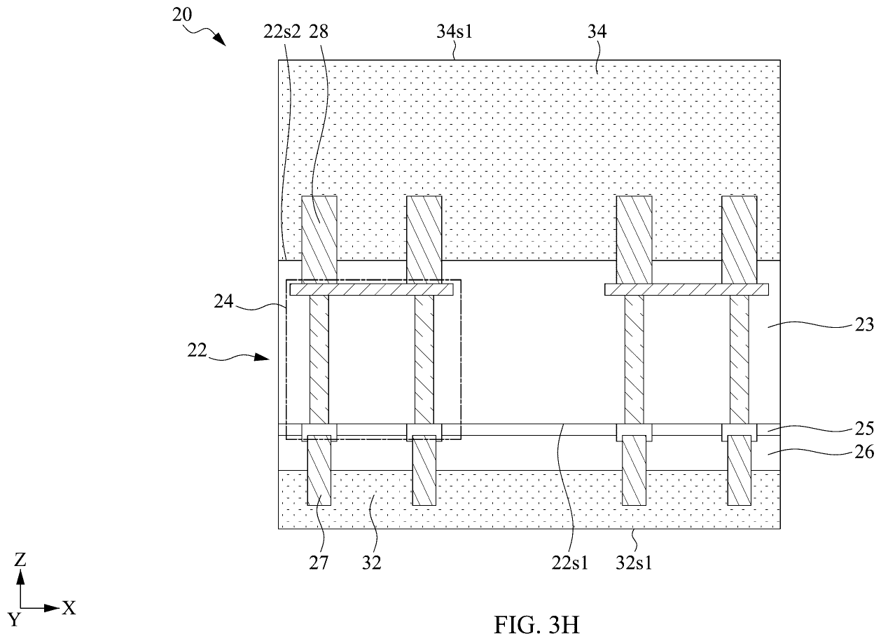

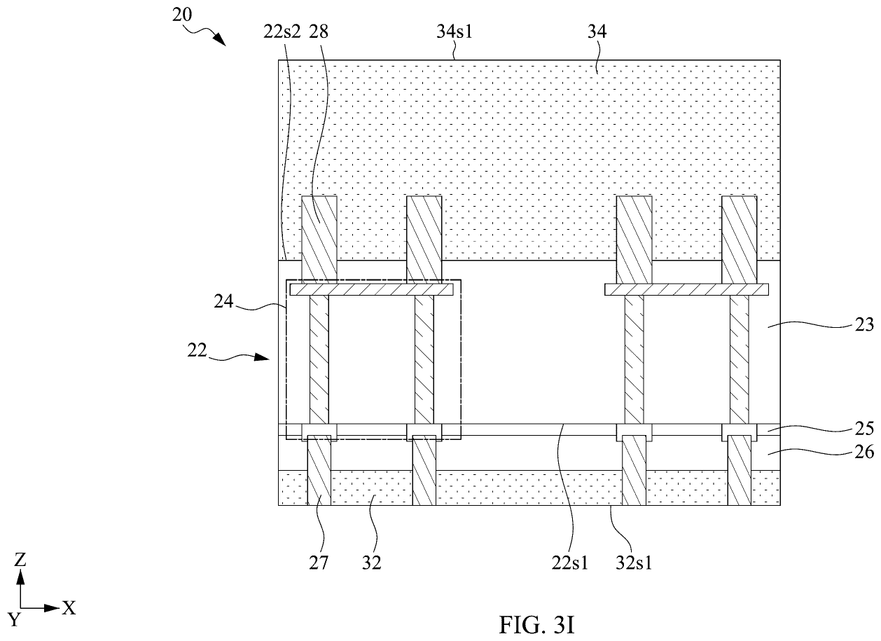

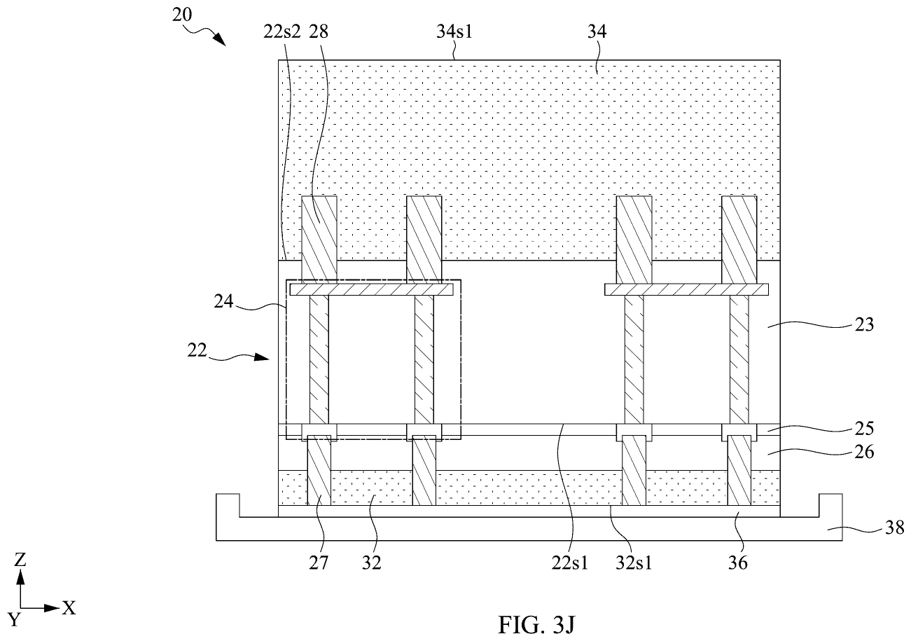

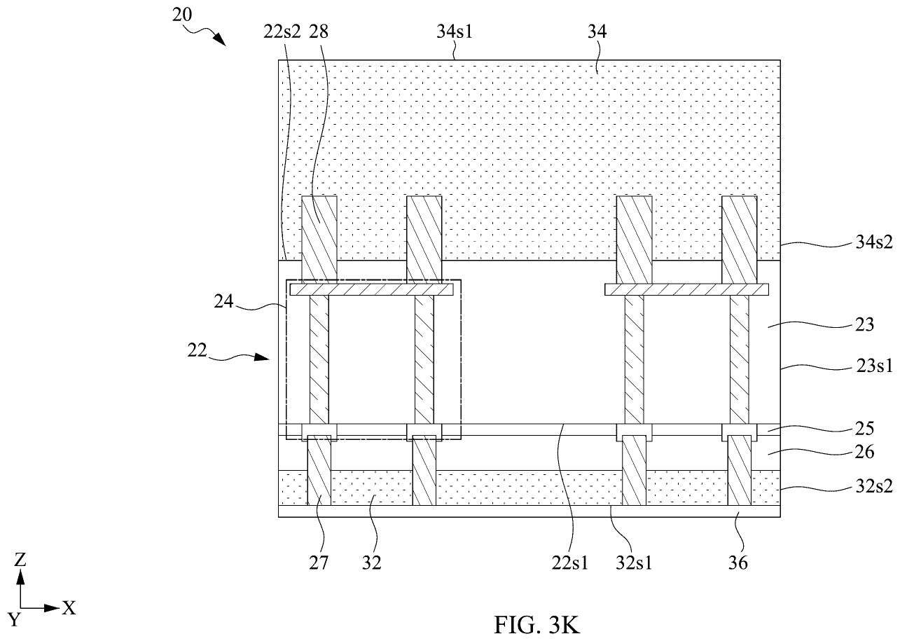

FIG 3A, FIG. 3B, FIG. 3C, FIG. 3D, FIG. 3E, FIG. 3F, FIG. 3G, FIG. 3H, FIG. 3I, FIG. 3J, and FIG. 3K illustrate various stages of an example of a method for manufacturing the interposer 20 according to some embodiments of the present disclosure.

Referring to FIG. 3A, the passive component 22 may be provided. In this stage, a wafer may be provided. The wafer may include a plurality of repeated units (e.g., the passive component 22). The repeated units will be separated from each other after a singulation technique is performed. The passive component 22 may include the substrate 23 and the passive circuit 24 formed within the substrate 23.

Referring to FIG. 3B, the conductive structures 28 may be formed on the surface 22s1 of the passive component 22 to be electrically connected to the passive circuit 24. The conductive structures 28 may penetrate a portion of the substrate 23. The warpage-control layer 34 may be formed on the surface 22s2 of the passive component 22. The warpage-control layer 34 may cover and encapsulate the conductive structures 28. In some arrangements, the warpage-control layer 34 may be formed by a molding technique, such as compression molding, injection molding, transfer molding, or other suitable techniques.

Referring to FIG. 3C, a grinding technique or polishing technique may be performed on the surface 22s1 of the passive component 22 or on the lower surface of the substrate 23. A portion of the substrate 23 may be removed. A portion of the passive circuit 24 may be exposed.

Referring to FIG. 3D, an etching technique may be performed on the surface 22s1 of the passive component 22 or on the lower surface of the substrate 23 to form a recess 23r. In some arrangements, a portion of the passive circuit 24 may be protruded from the substrate 23.

Referring to FIG. 3E, the dielectric layer 25 may be formed on or under the surface 22s1 of the passive component 22 or on the lower surface of the substrate 23. In some arrangements, the dielectric layer 25 may fill the recess 23r. In some arrangements, the dielectric layer 25 may encapsulate a portion of the passive circuit 24. For example, the dielectric layer 25 may cover or be in contact with the lateral surface of the passive circuit 24. The dielectric layer 25 may be formed by, for example, chemical vapor deposition technique, atomic layer deposition technique, or other suitable techniques.

Referring to FIG. 3F, an etching technique may be performed on the dielectric layer 25. A portion of the dielectric layer 25 may be removed. A portion of the passive circuit 24 may be exposed by the dielectric layer 25.

Referring to FIG. 3G, the conductive structures 27 may be formed on or under the surface 22s1 of the passive component 22 or on the lower surface of the substrate 23. The conductive structures 27 may be electrically connected to the passive circuit 24. The protection layer 26 may be formed on or under the surface 22s1 of the passive component 22 or on the lower surface of the substrate 23. The protection layer 26 may encapsulate a portion of the conductive structures 27. In some arrangements, the conductive structures 27 may be protruded from the protection layer 26.

Referring to FIG. 3H, the warpage-control layer 32 may be formed under the protection layer 26. The warpage-control layer 32 may encapsulate a portion of the conductive structures 27. The interposer 20 may be produced. In some arrangements, the warpage-control layer 32 may be formed by a molding technique, such as compression molding, injection molding, transfer molding, or other suitable techniques.

Referring to FIG. 3I, a grinding or polishing technique may be performed on or under the surface 32s1 of the warpage-control layer 32. A portion of the warpage-control layer 32 may be removed. The conductive structures 27 may be exposed by the warpage-control layer 32.

Referring to FIG. 3J, a release film 36 may be attached to the surface 32s1 of the warpage-control layer 32. A carrier 38 may be provided. The carrier 38 may include a glass carrier, a semiconductor carrier, a ceramic carrier, or other suitable carriers. The wafer, including a plurality of passive components 22, may be attached to the carrier 38 by the release film 36. In some arrangements, the surface 32s1 of the warpage-control layer 32 may be attached to the carrier 38 through the release film 36.

Referring to FIG. 3K, a singulation technique may be performed. The carrier 38 may be removed from the interposer 20. A plurality of passive components 22 (or interposers 20) may be separated from each other. In some arrangements, the surface 34s2 of the warpage-control layer 34 may be substantially aligned with the lateral surface of the passive component 22 or aligned with the surface 23s1 of the substrate 23. In some arrangements, the surface 32s2 of the warpage-control layer 32 may be substantially aligned with the lateral surface of the passive component 22 or aligned with the surface 23s1 of the substrate 23.

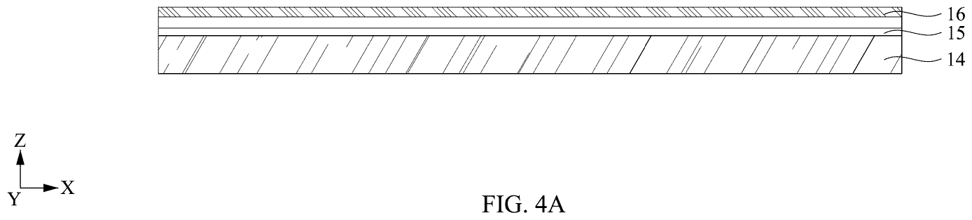

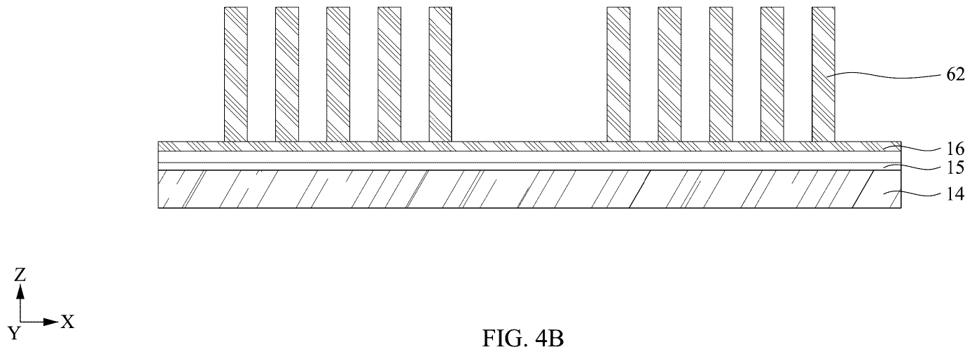

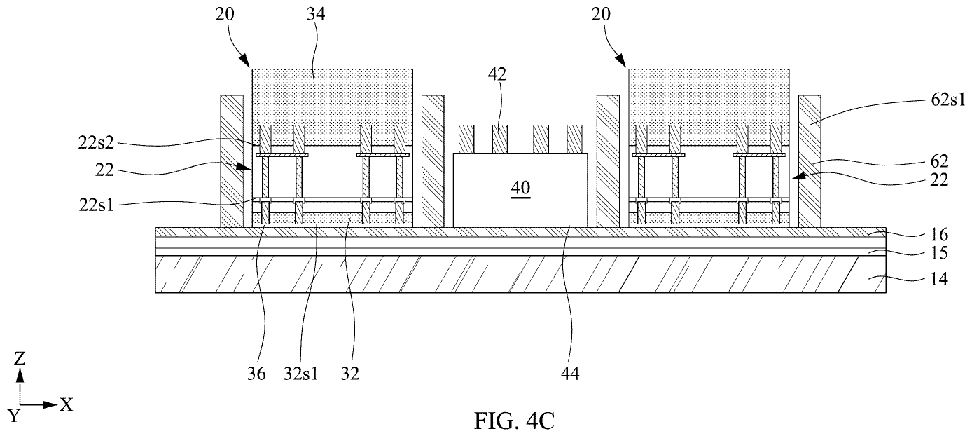

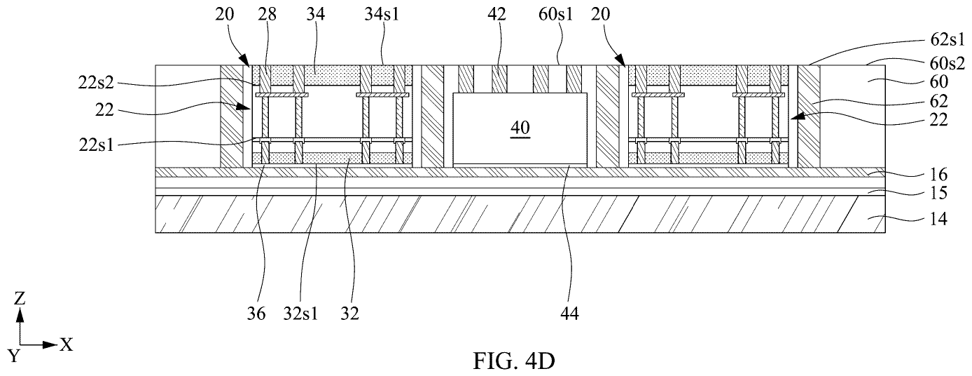

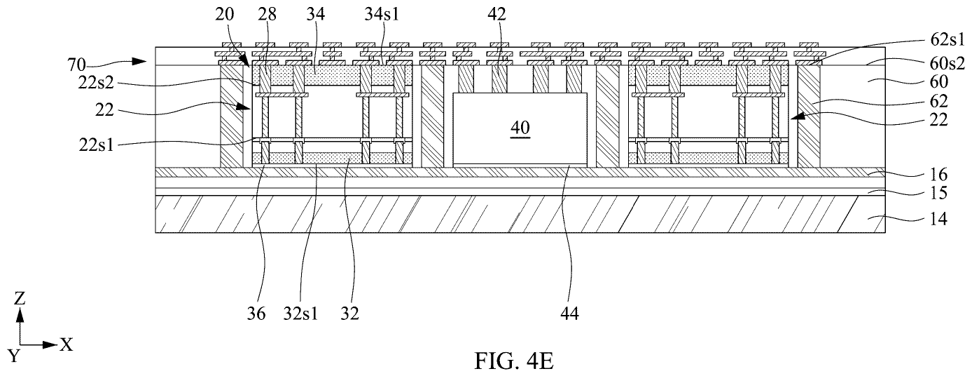

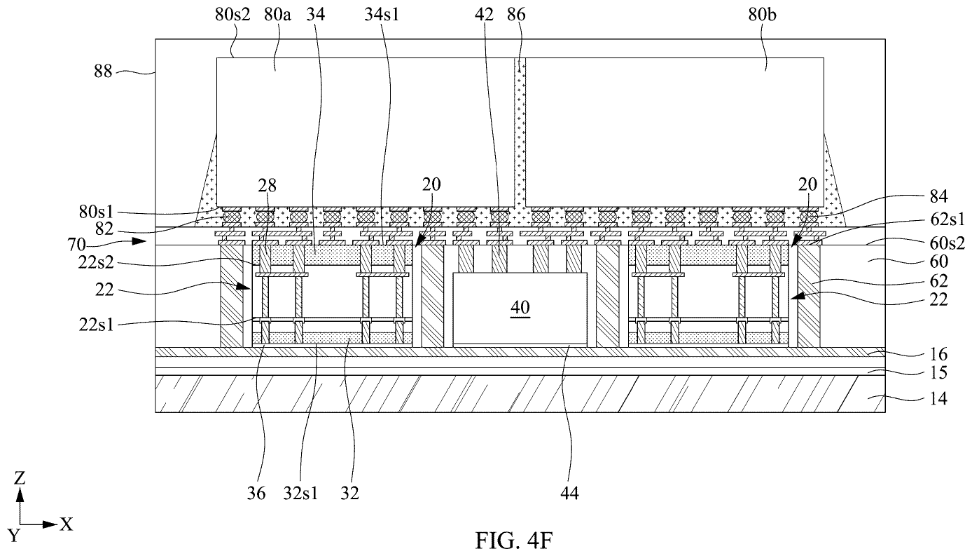

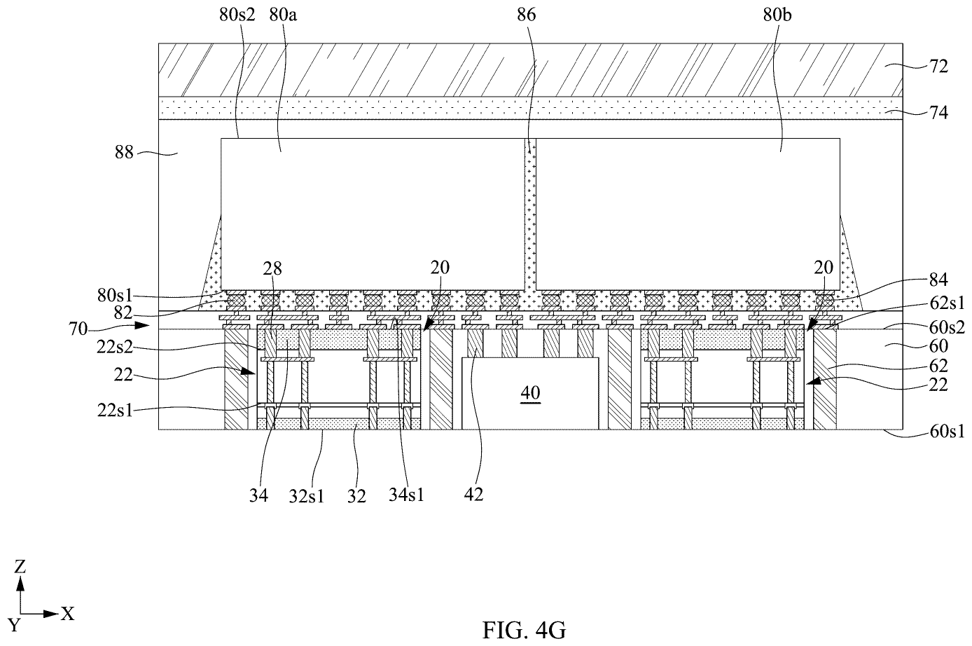

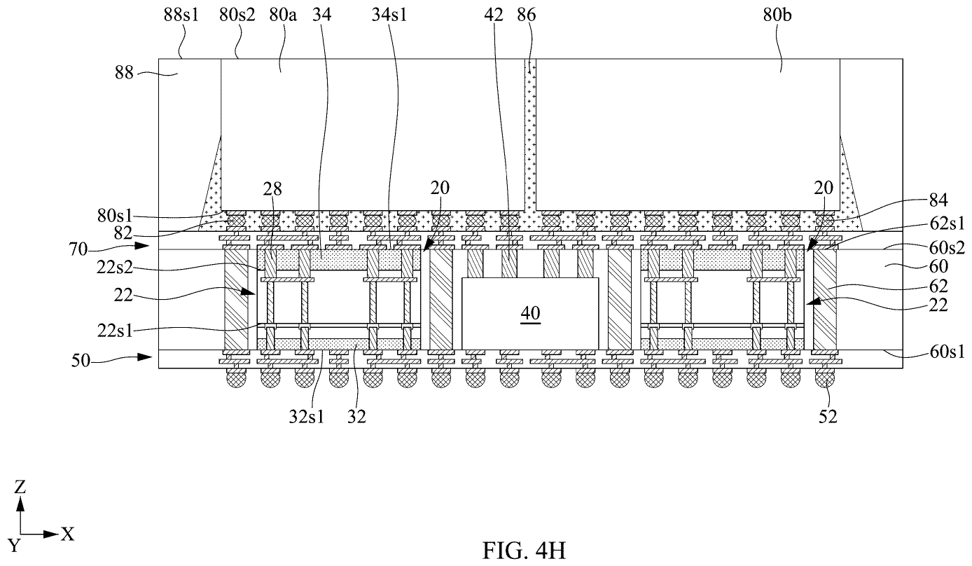

FIG. 4A, FIG. 4B, FIG. 4C, FIG. 4D, FIG. 4E, FIG. 4F, FIG. 4G, FIG. 4H, FIG. 4I, and FIG. 4J illustrate various stages of an example of a method for manufacturing the 1a according to some embodiments of the present disclosure. FIGS. 4A to 4J illustrate the stages of integrating the interposers 20, the bridge component 40, the electronic component 80a, and/or the electronic component 80b.

Referring to FIG. 4A, a carrier 14 may be provided. The carrier 14 may include a glass carrier, a semiconductor carrier, a ceramic carrier, or other suitable carriers. A release film 15 may be formed on the carrier 14. A seed layer 16 may be formed on the release film 15. The seed layer 16 may include, for example, copper, tungsten, a combination thereof, or other suitable materials.

Referring to FIG. 4B, the conductive pillars 62 may be formed on or over the seed layer 16. In some arrangements, the conductive pillars 62 may be formed by a sputter technique or other suitable techniques.

Referring to FIG. 4C, the interposers 20 and the bridge component 40 may be attached to the seed layer 16. In some arrangements, the interposer 20 may be attached to the seed layer 16 by the release film 36. The interposer 20 may be spaced apart from the seed layer 16 by the warpage-control layer 32. The bridge component 40 may be attached to the seed layer 16 by an adhesive 44. The adhesive 44 may include, for example, a die attach film (DAF) or other suitable materials.

Referring to FIG. 4D, the encapsulant 60 may be formed on or over the seed layer 16. The encapsulant 60 may encapsulate the interposer 20, the bridge component 40, and the conductive pillar 62. In some arrangements, the encapsulant 60 may be formed by a molding technique, such as compression molding, injection molding, transfer molding, or other suitable techniques. In some arrangements, a grinding or polishing technique may be performed to remove an excessive portion of the encapsulant 60. As a result, the conductive structures 28 may be exposed by the encapsulant 60. The interconnectors 42 may be exposed by the encapsulant 60. In this stage, a portion of the warpage-control layer 34 may be removed, and a portion of the interconnectors 42 may be removed. The surface 60s2 of the encapsulant 60 may be substantially aligned with the surface 34s1 of the warpage-control layer 34. A surface 62s1 of the conductive pillar 62 may be substantially aligned with the surface 60s2 of the encapsulant 60.

Referring to FIG. 4E, the redistribution structure 70 may be formed on or over the encapsulant 60. The redistribution structure 70 may be formed on or over the interposer 20. The redistribution structure 70 may be formed on or over the bridge component 40. The redistribution structure 70 may be formed on or over the conductive pillars 62.

Referring to FIG. 4F, the electronic components 80a and 80b may be attached to the redistribution structure 70 by the electrical connections 84. The protection layer 86 may be formed to encapsulate the electrical connections 84. The encapsulant 88 may be formed on or over the redistribution structure 70 to encapsulate the electronic components 80a and 80b. In some arrangements, the encapsulant 88 may be formed by a molding technique, such as compression molding, injection molding, transfer molding, or other suitable techniques.

Referring to FIG. 4G, the encapsulant 88 may be attached to a carrier 72 through a release film 74. The carrier 72 may include a glass carrier, a semiconductor carrier, a ceramic carrier, or other suitable carriers. The carrier 14, release film 15, and seed layer 16 may be removed. In some arrangements, the release film 36 may be removed from the interposer 20. In some arrangements, the adhesive 44 may be removed from the bridge component 40. The lower surface of the conductive pillar 62 may be exposed. The surface 32s1 of the warpage-control layer 32 may be exposed.

Referring to FIG. 4H, the redistribution structure 50 may be formed on or under the surface 60s1 of the encapsulant 60. The redistribution structure 50 may be formed on or under the interposer 20. The redistribution structure 50 may be formed on or under the conductive pillars 62. The redistribution structure 50 may be formed on or under the bridge component 40. The electrical connections 52 may be formed on or under the redistribution structure 50. The carrier 72 and release film 74 may be removed. In some arrangements, the adhesive 44 and the release film 36 may be removed. In some arrangements, the adhesive 44 and the release film 36 may remain.

Referring to FIG. 4I, a grinding or polishing technique may be performed to remove an excessive portion of the encapsulant 88. As a result, the surface 80s2 of the electronic component 80a (or electronic component 80b) may be exposed by the encapsulant 88. In some arrangements, the conductive layer 90 may be formed on or over the electronic component 80a, electronic component 80b, and encapsulant 88.

Referring to FIG. 4J, a singulation technique may be performed. As a result, the lateral surfaces of the encapsulant 60 and encapsulant 88 may be substantially aligned. The electrical connections 52 may be attached to the circuit structure 10. The protection layer 54 may be formed on or over the circuit structure 10 to encapsulate the electrical connections 52. The electrical connections 12 may be formed on or under the surface 10s1 of the circuit structure 10. As a result, the electronic device 1a may be produced.

In the stage as shown in FIG. 4C, the interposer 20, which includes warpage-control layers 32 and 34, is attached to the seed layer 16. The warpage-control layers 32 and 34 help to minimize the overall warpage of the interposer 20. At this stage, the warpage-control layer 34 has a relatively large thickness, which will be reduced in the subsequent stage shown in FIG. 4D, where the excess portion of encapsulant 60 is removed. Throughout these stages, the warpage of the interposer 20 can be effectively reduced, thereby enhancing the manufacturing yield of electronic device 1a.

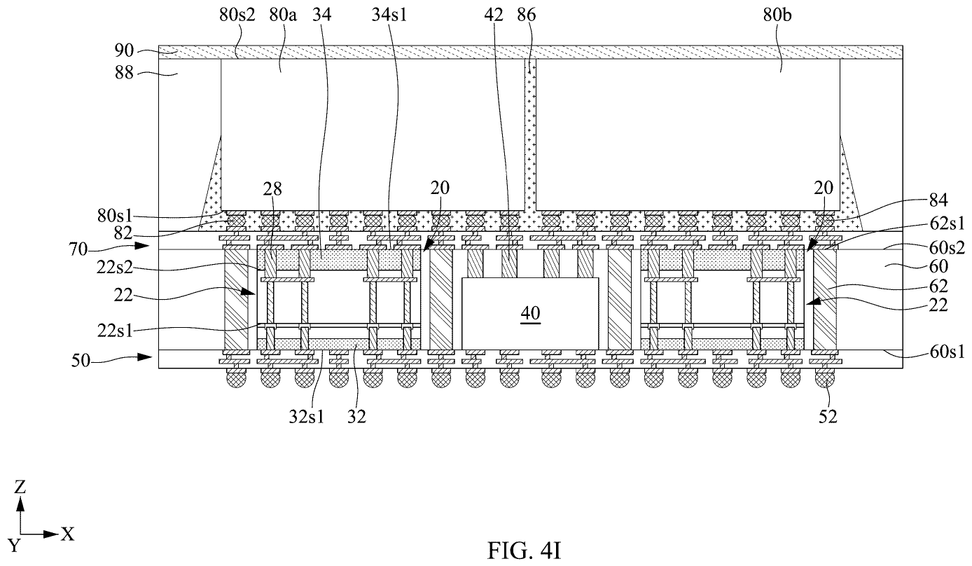

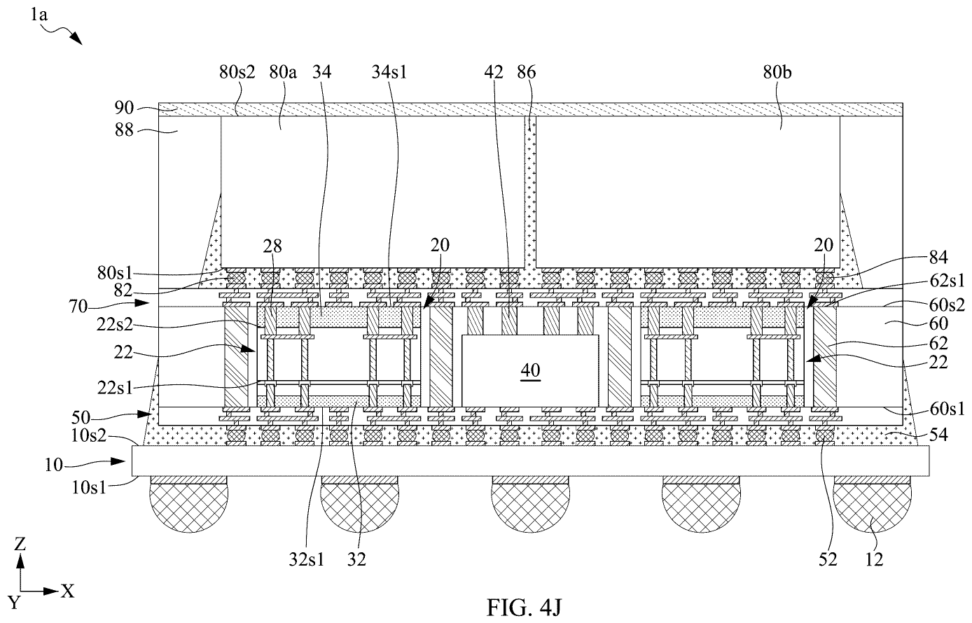

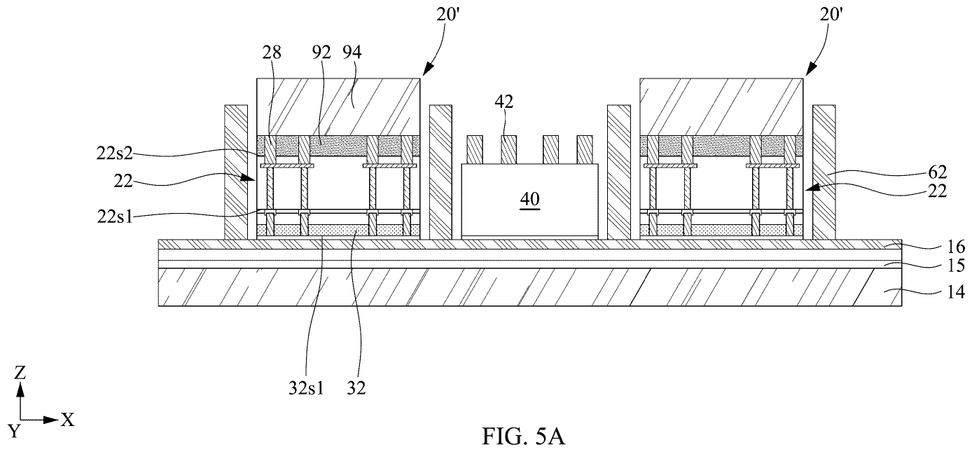

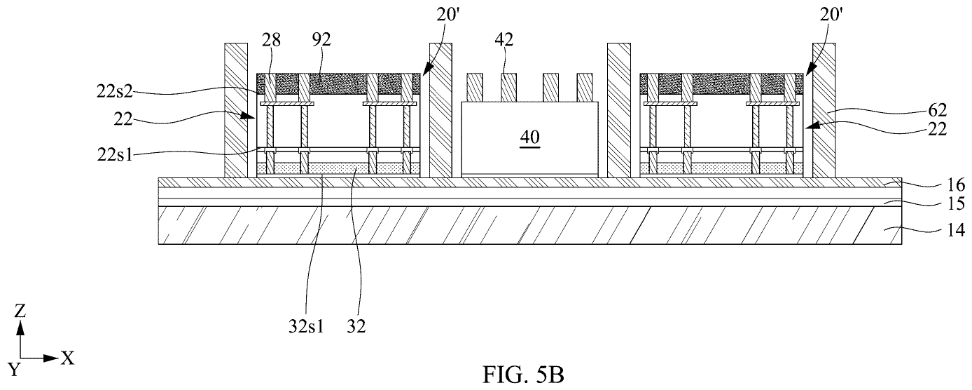

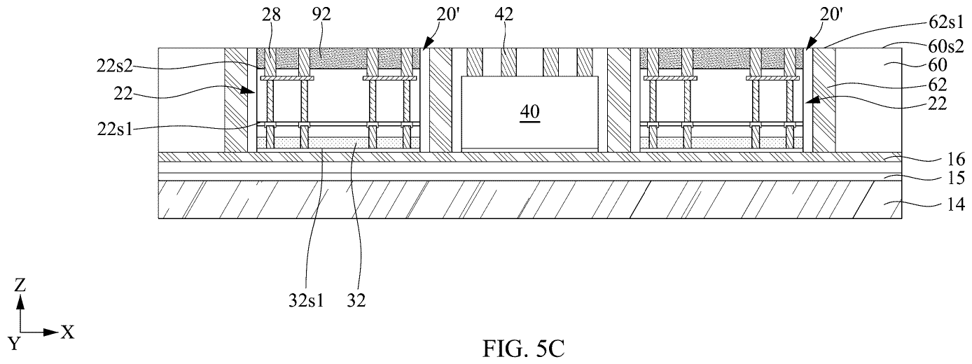

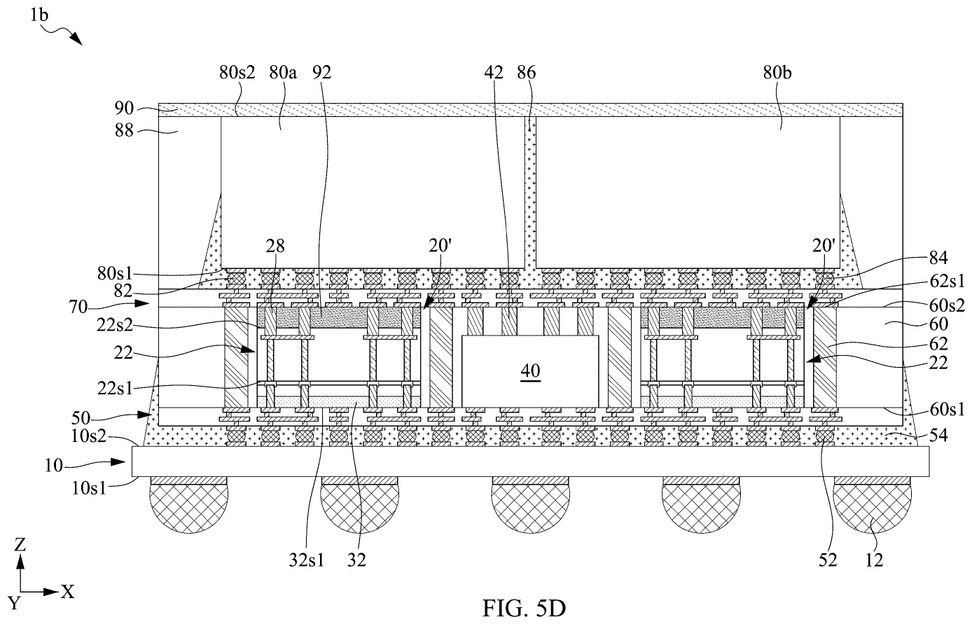

FIG. 5A, FIG. 5B, FIG. 5C, and FIG. 5D illustrate various stages of an example of a method for manufacturing an electronic device 1b according to some embodiments of the present disclosure.

Referring to FIG. 5A, interposes 20′ may be provided. In some arrangements, the interposer 20′ may have a structure similar to the interposer 20, and one of the differences is that the warpage-control layer 34 of the interposer 20 is replaced by a protection layer 92 and a warpage-control element 94. In some arrangements, at the stage as shown in FIG. 3B, after the conductive structures 28 are formed, the protection layer 92 may be formed on or over the surface 22s2 to encapsulate the conductive structures 28. The protection layer 92 may include polyimide, polybenzoxazole, benzocyclobuten, or other suitable materials. In some arrangements, the warpage-control element 94 may be formed on or over the protection layer 92. The warpage-control element 94 may be configured to reduce the warpage of the interposer 20′. In some arrangements, the warpage-control element 94 may include a silicon substrate, a glass substrate, or other suitable elements.

Referring to FIG. 5B, the warpage-control element 94 may be removed. The protection layer 92 may be exposed.

Referring to FIG. 5C, the encapsulant 60 may be formed. In some arrangements, a grinding or polishing technique may be performed to remove an excessive portion of the encapsulant 60. In this stage, a portion of the protection layer 92 may be removed. The surface 60s2 of the encapsulant 60 may be substantially aligned with the upper surface of the warpage-control element 94.

Referring to FIG. 5D, the stages as shown in FIGS. 4E to 4J may be performed, and the electronic device 1b may be produced.

In the stage as shown in FIG. 5A, the interposer 20′, including the warpage-control layer 32 and warpage-control element 94, are attached to the seed layer 16. The warpage-control layer 32 and warpage-control element 94 may reduce the overall warpage of the interposer 20′. Therefore, the manufacturing yield of the electronic device 1b may be improved.

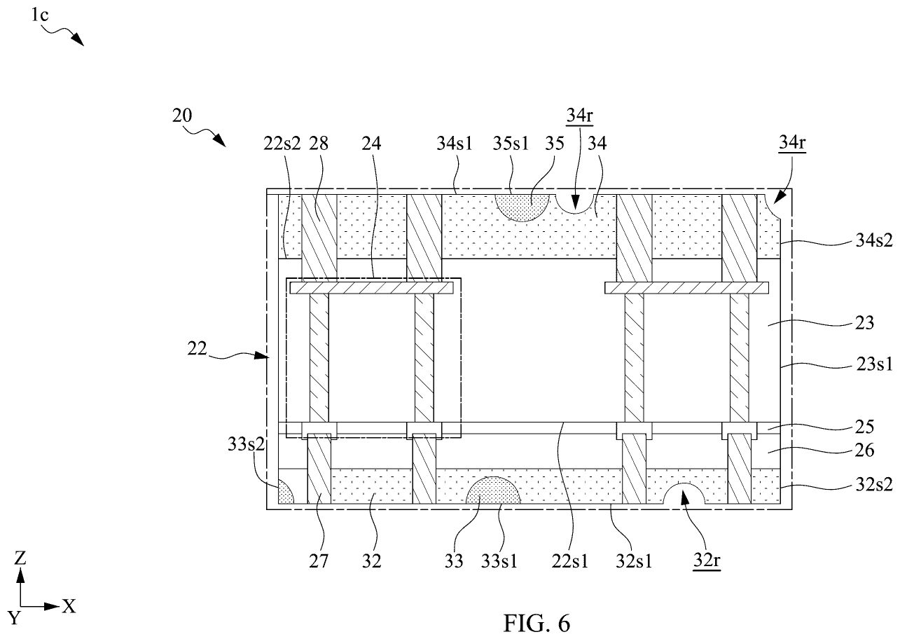

FIG. 6 illustrates a cross-sectional view of an electronic device 1c, in accordance with some arrangements of the present disclosure.

In some arrangements, some of the fillers 33 of the structure may drop from the structure as shown in FIG. 2. A recess 32r may be formed. The recess 32r may be recessed from the warpage-control layer 32. In some arrangements, the recess 32r may be filled with the encapsulant 60. In some arrangements, the recess 32r may be filled with the air. In some arrangements, the recess 32r may be disposed at the corner of the warpage-control layer 32. In some arrangements, some of the fillers 35 of the structure may drop from the structure as shown in FIG. 2. A recess 34r may be formed. The recess 34r may be recessed from the warpage-control layer 34. In some arrangements, the recess 34r may be filled with the encapsulant 60. In some arrangements, the recess 34r may be filled with the air. In some arrangements, the recess 34r may be disposed at the corner of the warpage-control layer 34.

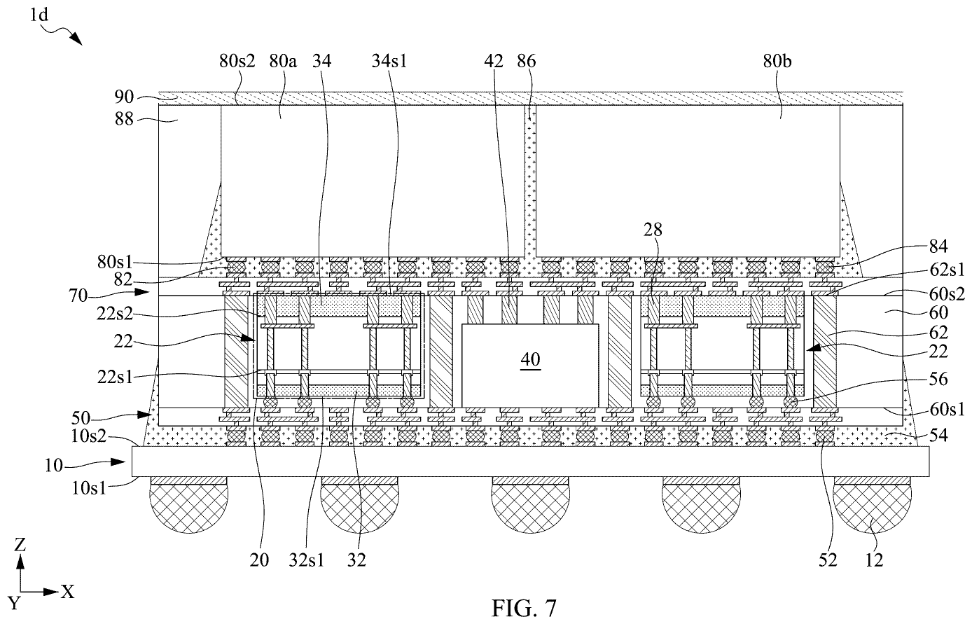

FIG. 7 illustrates a cross-sectional view of an electronic device 1d, in accordance with some arrangements of the present disclosure.

In some arrangements, the electronic device 1d may include electrical connections 56. The electrical connections 56 may include a reflowable material. The electrical connections 56 may be or include electrical contacts, such as solder balls (e.g., controlled collapse chip connection (C4) bump, a ball grid array (BGA), a land grid array (LGA)), conductive bumps, or the like. The electrical connections 56 may include alloys of gold and tin solder or alloys of silver and tin solder, or other suitable materials. The electrical connections 56 may be disposed between and electrically connect the interposer 20 and the redistribution structure 50.

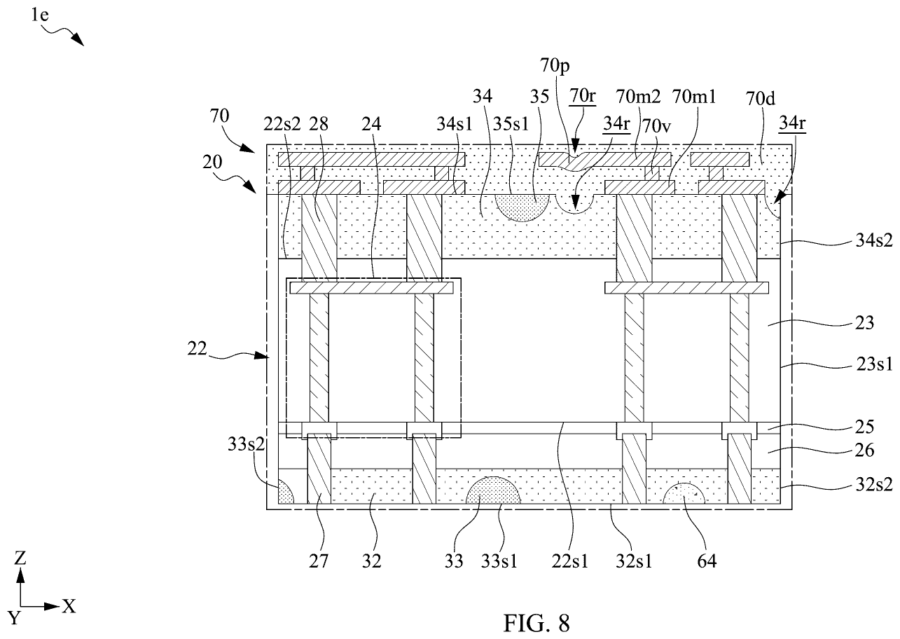

FIG. 8 illustrates a cross-sectional view of an electronic device 1e, in accordance with some arrangements of the present disclosure.

In some arrangements, the recess 32r of the warpage-control layer 32 as shown in FIG. 6 may be filled with the material included in the encapsulant 60. For example, the recess 32r of the warpage-control layer 32 as shown in FIG. 6 may be filled with fillers 64 of the encapsulant 60. In other arrangements, the recess 32r of the warpage-control layer 32 as shown in FIG. 6 may be filled with the resin material (not shown) of the encapsulant 60.

In some arrangements, the recess 34r of the warpage-control layer 34 as shown in FIG. 6 may be filled with the material included in redistribution structure 70. For example, the recess 34r of the warpage-control layer 34 as shown in FIG. 6 may be filled with a dielectric layer 70d (e.g., polyimide). In this arrangement, the dielectric layer 70d may have protruding portions filling the recess 34r. Each of the protruding portions of the dielectric layer 70d may have a partial circular or partial oval profile. For example, the recess 34r in the corner of the warpage-control layer 34 may be filled with the dielectric layer 70d.

The redistribution structure 70 may include a conductive layer 70m1 and a conductive layer 70m2 over the conductive layer 70m1. The conductive layer 70m2 may be connected to the conductive layer 70m1 by a via 70v. The conductive layers 70m1, 70m2, and the via 70v may be embedded within the dielectric layer 70d. In some cases, the material of the dielectric layer 70d may fill the recess 34r of the warpage-control layer 34, and the dielectric layer 70d may define a recess (not labeled) partially conformal to the profile of the recess 34r during manufacturing processes. In this condition, the conductive layer 70m2 may include a protruding portion 70p filling the recess of the dielectric layer 70d and define a recess 70r recessed from the upper surface of the conductive layer 70m2.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a passive component having a lower surface and an upper surface opposite to the lower surface;
a first warpage-control layer disposed under the lower surface; and
a second warpage-control layer disposed over the upper surface.

2. The electronic device of claim 1, wherein a thickness of the first warpage-control layer is different from a thickness of the second warpage-control layer.

3. The electronic device of claim 2, further comprising:
an encapsulant encapsulating the passive component and having an upper surface substantially aligned with an upper surface of the second warpage-control layer.

4. The electronic device of claim 3, further comprising:
a conductive element disposed at a side of the passive component and penetrating the encapsulant.

5. The electronic device of claim 3, further comprising:
a first electronic component disposed over the upper surface of the passive component;
a second electronic component disposed over the upper surface of the passive component; and
a bridge component electrically connecting the first electronic component and the second electronic component,
wherein the bridge component laterally overlaps the passive component.

6. The electronic device of claim 5, wherein the bridge component has a lower surface substantially aligned with a lower surface of the first warpage-control layer.

7. The electronic device of claim 5, further comprising:
a redistribution structure disposed between the first electronic component and the second warpage-control layer.

8. The electronic device of claim 1, wherein the first warpage-control layer comprises at least one filler having a truncated surface exposed by a lower surface of the first warpage-control layer.

9. The electronic device of claim 1, wherein the second warpage-control layer comprises at least one filler having a truncated surface exposed by an upper surface of the second warpage-control layer.

10. The electronic device of claim 1, wherein the passive component comprises a substrate and a passive circuit penetrating the substrate, and the substrate is spaced apart from the first warpage-control layer.

11. The electronic device of claim 10, wherein the passive component comprises:
a dielectric layer between the substrate and the first warpage-control layer; and
a first conductive structure connected to the passive circuit,
wherein the first conductive structure penetrates the dielectric layer and the first warpage-control layer.

12. An electronic device, comprising:
a redistribution structure;
a first electronic component over the redistribution structure;
a passive component under the redistribution structure and electrically connected to the first electronic component; and
a first warpage-control layer between the redistribution structure and the passive component.

13. The electronic device of claim 12, further comprising:
a carrier supporting the passive component; and
a second warpage-control layer between the passive component and the carrier.

14. The electronic device of claim 13, wherein a thickness of the first warpage-control layer is greater than a thickness of the second warpage-control layer.

15. The electronic device of claim 12, wherein the first warpage-control layer comprises at least one filler having a truncated surface exposed by a lateral surface of the first warpage-control layer.

16. The electronic device of claim 15, further comprising:
an encapsulant in contact with the truncated surface.

17. The electronic device of claim 16, further comprising:
a second warpage-control layer spaced apart from the first warpage-control layer by the passive component,
wherein the encapsulant encapsulates the first warpage-control layer and the second warpage-control layer.

18. The electronic device of claim 12, further comprising:
a carrier supporting the passive component, wherein the passive component is disposed between the carrier and the redistribution structure.

19. A method of manufacturing an electronic device, comprising:
providing a passive component having a first surface and a second surface opposite to the first surface;
forming a first warpage-control layer under the first surface;
forming a second warpage-control layer over the second surface to define an interposer; and
integrating the interposer with an electronic component.

20. The method of claim 19, further comprising:
providing a carrier;
attaching the interposer to the carrier through the first warpage-control layer; and
removing the carrier.
